(19) United States
(12) Patent Application Publication
(10) Pub. No.: US 2015/0041060 A1
(43) Pub. Date: Feb. 12, 2015

(54) PLASMA PROCESSING APPARATUS

(71) Applicant: Hitachi High-Technologies Corporation, Tokyo (JP)

(72) Inventors: Kousa Hirota, Tokyo (JP); Tatehito Usui, Tokyo (JP); Satomi Inoue, Tokyo (JP); Shigeru Nakamoto, Tokyo (JP)

(21) Appl. No.: 14/182,497

(22) Filed: Feb. 18, 2014

(30) Foreign Application Priority Data
Aug. 6, 2013 (JP) 2013-163184

(51) Int. Cl. H01L 21/67

(52) U.S. Cl. CPC H01L 21/67069; H01L 21/67242
USPC 156/345.28

(57) ABSTRACT

A plasma processing apparatus includes a plasma forming part, a putting stage on which a wafer is put, a bias power supply which supplies high-frequency power to the putting stage and a detection part which detects amounts of positive and negative currents flowing between the bias power supply and the putting stage and a ratio of the positive and negative current amounts, and the plasma processing apparatus adjusts formation of the plasma or the plasma processing condition of the wafer in accordance with the ratio.

### BACKGROUND OF THE INVENTION

The present invention relates to a plasma processing apparatus which includes a processing chamber in a vacuum container in which a substrate-like sample such as a semiconductor wafer for fabricating a semiconductor device or the like is disposed and performs etching processing using plasma formed in the processing chamber and more particularly to a plasma processing apparatus including an electrode disposed in the processing chamber to put the sample thereon so as to support the sample and supplied with high-frequency power during processing.

With high integration and high-speed operation of semiconductor integrated circuits in recent years, further miniaturization of gate electrodes is required. However, since slight variation in the dimension of a gate electrode greatly varies source/drain current or leak current on standby, it is important to make it possible to process a layer to be etched on the surface of a sample (hereinafter referred to as a semiconductor wafer or wafer) to be processed containing the critical dimension (hereinafter abbreviated to CD) of the gate electrode into a desired shape with high accuracy and stably.

In order to stabilize the processed shape, it is required to reduce variation even temporally and even among plural parts for the surface state of a part disposed in a processing chamber in which etching processing is performed and further detect the processing end of the layer to be processed with high accuracy. However, byproducts produced during the etching processing are attached on the surface of inner part of the processing chamber during the etching processing or the composition of the surface of the inner part of the processing chamber is changed, so that the surface state of the etching processing chamber is changed with the progress of processing or increase of the number of etched wafers. When such change occurs, the probability of recombination of radicals on the surface of the processing chamber is changed even if plasma is generated in the processing chamber on the same condition and accordingly the density of radials in the plasma is changed, so that characteristics such as processing rate are changed and the processed shape is changed from that at the beginning of the processing.

With regard to such a problem, in the etching processing apparatus using a part made of aluminum, a product produced by variation in CD or during processing is attached on the surface of a wafer to thereby contaminate the surface and it is heretofore known that a so-called foreign substance is related to aluminum fluoride produced by aluminum material. Such a matter is disclosed in Plasma Sources Sci. Technol. 16 (2007) 711-715, for example.

Further, since wear of a part made of aluminum is faster as compared with another material, the period of exchange of the part made of aluminum is relatively short. As the exchange period is shorter, the time that processing is not performed is increased and accordingly the number of wafers per unit time to be processed by the plasma processing apparatus is reduced.

In contrast with this, ceramic material such as yttria having smaller wear for plasma is applied as material forming the surface of the inner part of the processing chamber. Reduction in wear as well as reduction of variation in the CD is attained effectively by using such ceramic having smaller wear, although it is cleared that variation in the long-term CD value presumed to be caused by change in the compositional state of the surface of yttria and deposit of byproducts produced by etching of a wafer occurs.

Namely, when an extremely large number of wafers are processed, it is difficult to maintain the surface state of the inner part of the processing chamber to be fixed during this processing. Accordingly, in order to maintain the CD value to be fixed even if the surface state is changed, it is considered that the processing conditions such as characteristics of plasma are controlled. For example, the technique that change in the emission intensity of plasma during the etching processing is detected to change pressure in the processing chamber, composition and flow rate/velocity of gas, intensity and distribution of electric field and magnetic field and the like, that is, the so-called recipe on the basis of the variation amount in the CD predicted from the detected change, so that variation in the CD value is suppressed is disclosed by JP-A-2004-241500 as APC (Advanced Process Control).

Further, JP-A-2004-296612 discloses that a monitor for detecting a plasma impedance in a circuit in which an electrode disposed in a processing chamber is constructed through plasma and a network analyzer are used to detect the plasma impedance with high accuracy and adjust conditions of forming plasma such as high-frequency power, pressure, gas ratio and the like so that an expected plasma impedance is attained, so that the reproducibility of processing is made higher. Furthermore, JP-A-11-054486 discloses the technique that the etching end is judged with high accuracy in order to maintain the processed shape to be fixed and accordingly the results of detecting emission of light from plasma and plasma impedance are used to judge the end of etching processing from the change thereof.

### SUMMARY OF THE INVENTION

In the above prior arts, consideration to the following points is insufficient and accordingly it is apprehended that there arises a problem for a future apparatus.

Namely, in the apparatus disclosed in JP-A-2004-241500, the emission of light from plasma is detected in order to presume the CD value or its variation amount, although when material having low transmissivity of light emission from plasma, for example, yttria or the like is used as material for the surface of a wall in the inner part of the processing chamber, it is difficult to obtain sufficiently strong light if such a wall surface is disposed in the optical path, so that the detection accuracy is reduced. Further, the problem that when byproducts produced during processing and which are material having high absorptivity or reflectivity of light are attached on the surface of a part facing plasma in the inner part of the processing chamber and an amount of deposit thereof is increased with increase of the number of wafers processed or when physical properties such as absorptivity or reflectivity of light of material of the processing chamber are changed over the years, the intensity of the received light is varied and it is difficult to obtain sufficient emission intensity and make judgment with high accuracy, so that the high-accurate processing required in the future cannot be performed is not considered in the above prior art. Further, in the prior art, since what plasma emission is performed is limited to atoms or molecules of allowed transition of plasma in the processing chamber, it is difficult to detect change in amount or distribution of atom species and molecule species of forbidden transition. In order to perform the high-accurate processing required in the future, it is expected that the above matters are to be considered.

Furthermore, the light emission from atoms and molecules is made by deexcition of the atoms and the molecules from an upper level to a lower level at a certain transition probability after the atoms and molecules receive energy of electrons mainly to be excited to the upper level. Accordingly, when the density of electrons having high energy existing in plasma is small or when the transition probability is low or further when the processing accuracy to be requested becomes high and the dimension of grooves or holes formed by etching and the CD value are small, so that the ratio (for example, aperture ratio) of the area of the surface of a layer to be processed and facing plasma and the inner part of the processing chamber to the area of the upper surface of a single wafer is small, an amount of the material in plasma is small and accordingly the emission intensity itself is small, so that its detection is difficult.

Accordingly, the case where the emission intensity is not obtained sufficiently occurs according to the kind of material of the layer to be etched and a condition of introduction of gas introduced into the processing chamber in order to perform etching by physical or chemical reaction. In such a case, the problem that high-accurate end judgment required in the future cannot be attained by the end judgment technique disclosed in JP-A-11-054486 is not considered in the prior art.

Further, the plasma impedance monitor and the network analyzer disclosed in JP-A-2004-296612 require a large number of components of the apparatus and have to obtain data for reference of impedance corresponding to process conditions before mass production. Accordingly, it is apprehended that there arises a problem that it requires a lot of work and time to mount them on the apparatus and operate them in accordance with working of the mass production.

It is an object of the present invention to provide a plasma processing apparatus which can perform processing with high accuracy. Further, it is another object of the present invention to provide a plasma processing apparatus which can judge the end of processing with high accuracy.

In order to solve the above problems, the configuration and the processing procedure described in the Claims are adopted, for example.

According to the present invention, plural unit for solving the above problems are contained, although the plasma processing apparatus according to an aspect of the present invention, for example, includes a processing container having a processing chamber disposed therein and from which processing gas is exhausted, a unit to supply an electric field in the processing chamber to form plasma using processing gas supplied in the processing chamber, a putting stage disposed in the processing chamber to put a wafer thereon, a bias power supply to supply high-frequency power to an electrode disposed in the putting stage and a detection part to detect amounts of positive and negative currents flowing between the bias power supply and the putting stage and detect a ratio of the negative current amount and the positive current amount from which part caused by electrons in the plasma is removed.

Formation of the plasma or processing condition using the plasma of a layer to be processed and disposed on the wafer is adjusted in accordance with the ratio.

Further, the plasma processing apparatus detects an end of processing using the plasma on the basis of change in the ratio.

Furthermore, according to another aspect of the present invention, the plasma processing apparatus includes a processing container having a processing chamber disposed therein and from which processing gas is exhausted, a unit to supply an electric field in the processing chamber to form plasma using processing gas supplied in the processing chamber, a putting stage disposed in the processing chamber to put a wafer thereon, a bias power supply to supply high-frequency power to an electrode disposed in the putting stage and a detection part to detect amounts of positive and negative currents flowing between the bias power supply and the putting stage and detect a ratio of the negative current amount (I−) and the positive current amount (I+).

Formation of the plasma or processing condition using the plasma of a layer to be processed and disposed on the wafer is adjusted in accordance with a value in a range in which the ratio (I−/I+) is smaller than 1.

According to the present invention, since the formation of plasma or the processing condition is adjusted on the basis of detection result of change in amounts of positive and negative ions in the plasma in the processing chamber, the processing accuracy of the wafer is improved. Further, since the end of etching is judged on the basis of the detection result of the change, judgment accuracy is improved.

The other objects, features and advantages of the invention will become apparent from the following description of the embodiments of the invention taken in conjunction with the accompanying drawings.

### BRIEF DESCRIPTION OF THE DRAWINGS

FIG. 1 is a longitudinal sectional view schematically illustrating a plasma processing apparatus according to an embodiment of the present invention;

FIG. 2 is a graph showing change in a current value detected by a current detector in the plasma processing apparatus according to the embodiment shown in FIG. 1 versus change in time as a waveform;

FIG. 3 is a circuit diagram schematically illustrating the current detector in the plasma processing apparatus according to the embodiment shown in FIG. 1;

FIG. 4 is a graph showing electrical frequency characteristics of the circuit of the current detector in the plasma processing apparatus according to the embodiment shown in FIG. 3;

FIG. 5 is a graph showing the power dependence characteristic (every 100 W from 600 W to 1100 W) of the current ratio in case where plasma etching is performed on the condition of Cl₂ plasma;

FIG. 6 is a flow chart showing the flow of setting constants of elements constituting the circuit of the current detector shown in FIG. 3;

FIG. 7 is a graph showing the cut-off frequency dependence characteristic of the positive and negative current ratio in case where plasma etching is performed on the condition of SF₆/O₂/Ar=200/10/5 cc;

FIG. 8 is a flow chart showing the flow of operation in case where a plurality of wafers are processed in the embodiment shown in FIG. 1;

FIG. 9 is a graph showing the relation of the dependence characteristic on the number of wafers to be processed of CD after etching processing of wafer products, the positive and negative current ratio (ratio of output A 304 and output B 305) in in-situ Cleaning and the number of wafers to be processed;

FIG. 10 is a graph showing the dependence characteristic of the number of wafers to be processed of CD in case where over-etching time during etching of products is controlled on the basis of CD predicted by expression (1) to perform mass production of about ten thousand wafers;

FIG. 11 is a graph showing the positive and negative current ratio and the thickness of remaining layer of the layer to be processed obtained during the etching processing using the plasma processing apparatus according to the embodiment shown in FIG. 1;

FIG. 12 is a picture (SEM image) showing a section of the layer structure as a result of judgment of the processing end using the outputs of the current detector in the plasma processing apparatus according to the embodiment shown in FIG. 1; and

FIG. 13 is a graph showing the added-up value of outputs of the current detector in the plasma processing apparatus according to the embodiment shown in FIG. 1 and the emission intensity versus change in time.

### DESCRIPTION OF THE EMBODIMENTS

Embodiments of the present invention are now described with reference to the accompanying drawings.

### Embodiment 1

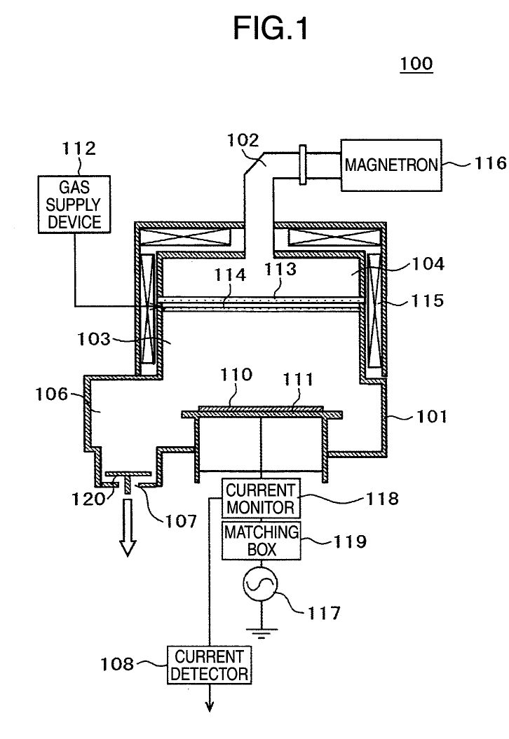

Referring now to FIGS. 1 to 10, an embodiment of the present invention is described.

FIG. 1 is a longitudinal sectional view schematically illustrating a plasma processing apparatus according to the embodiment of the present invention. In the embodiment, an example of an etching processing apparatus is illustrated in which a processing chamber is disposed in a vacuum container and the processing chamber has an inner part of a cylindrical shape which is evacuated to a predetermined vacuum degree. A semiconductor wafer (hereinafter referred to as a wafer) which is a sample to be processed is disposed on the surface of a sample stage disposed in the processing chamber. A layer to be processed of a layer structure formed previously in the surface of the wafer and made of plural lamination layers in the up and down direction is subjected to etching processing using plasma formed by introducing processing gas into space above the sample stage in the processing chamber and exciting particles of the gas by an electric field or magnetic field supplied externally of the vacuum container in the space.

An etching processing apparatus 100 which is one of the plasma processing apparatus according to the embodiment includes a processing chamber 103 having a cylindrical shape in the inner part of a vacuum container 101 and a putting stage 111 having the upper surface on which a wafer 110 to be processed is put is disposed in the processing chamber 103. Further, a ceiling plate 113 constituting a ceiling surface of the processing chamber 103 is disposed in the cylindrical upper part of the vacuum container 101. The undersurface of the outer peripheral part of the ceiling plate 113 is in contact with the upper end part of the cylindrical part of the processing chamber 103 and the inner part of the processing chamber 103 is hermetically sealed from the external atmosphere by a sealing part disposed therebetween.

Further, a shower plate 114 disposed in the processing chamber 103 below the ceiling plate 113 which microwave described later passes through to be introduced into the processing chamber 103 and which is made of dielectric such as quartz is disposed in the opposing relation to the putting plane of the wafer 110 of the putting stage 111 disposed below and in the facing manner to the processing chamber 103 so that a gap is formed between the shower plate 114 and the ceiling plate 113. A plurality of introduction holes which the processing gas passes through to flow into the processing chamber 103 from above are disposed in the area positioned opposite to the putting plane of the putting stage 111 at the central part of the shower plate 114 and on which the processing gas is projected to pass through the shower plate 114 in up and down direction.

A gas supply device 112 communicates with or is coupled with a gap between the ceiling plate 113 and the shower plate 114 in the vacuum container 101 to adjust supply of the processing gas on a supply route of the processing gas supplied into the gap. Further, a unit for supplying an electric field and a magnetic field in the processing chamber 103 to form plasma is disposed above the processing chamber 103 of the vacuum container 101.

The plasma forming unit includes a wave guide 102 which is a pipeline extending in the up and down direction and in the right and left (horizontal) direction to propagate an electric field through its inner part, a cavity 104 having inner cylindrical space coupled with the lower end in the up and down direction of the wave guide 102 and in which the electric field introduced into the inner space from the wave guide 102 is excited in a specific mode, a magnetron 116 disposed in upper end part of the wave guide 102 to oscillate an electric field (in the embodiment, electric field of microwave) and a solenoid coil 115 which is a magnetic field generation unit disposed in outer peripheral part of the processing chamber 103 of the vacuum container 101, the cavity 104 and part of the wave guide 102 extending in the up and down direction to supply the magnetic field in the processing chamber 103.

An electrode of conductive material such as metal is disposed in the putting stage 111 disposed in the lower part of the processing chamber 103 and the electrode is electrically connected through wiring such as cable to a bias power supply 117 which supplies high-frequency power for forming bias potential on the upper surface of the wafer during processing to induce charged particles such as ions in plasma so that the electrode is impressed with the high-frequency power. A current monitor 118 which detects current flowing through the cable is connected on the supply route of the high-frequency power by the cable and a matching box 119 is connected between the current monitor 118 and the bias power supply 117. Further, the current monitor 118 is electrically connected to a current detector 108, which uses signal transmitted from the current monitor 118 to detect an amount of current.

An exhaust chamber 106 is disposed in the side part of the putting stage 111 of the processing chamber 103 of the embodiment in communication with the processing chamber 103 to put an internal opening for exhaust between the exhaust chamber 106 and the processing chamber 103. The exhaust chamber 106 is space from which particles in plasma such as byproducts and particles of gas in the processing chamber 103 flowing into the exhaust chamber 106 in the right and left direction in the drawing and once staying therein flow out through an exhaust port 107 having a vacuum exhaust valve 120 which is opened and closed and disposed in the bottom of the vacuum container 101. The exhaust port 107 is coupled with a vacuum pump such as a turbo-molecular pump disposed below the exhaust port 107.

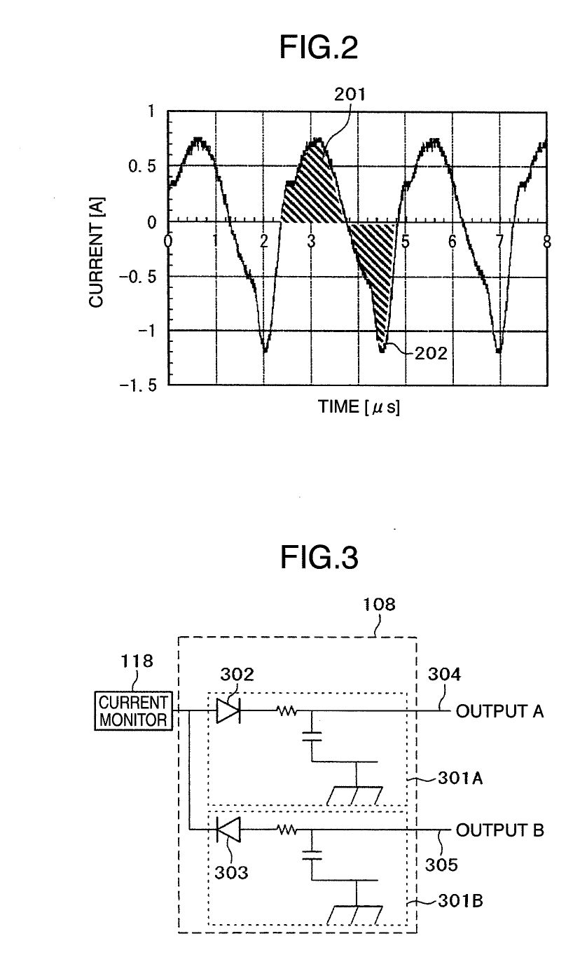

FIG. 2 is a graph showing change in the current value detected by the current detector according to the embodiment shown in FIG. 1 versus change in time as a waveform. In FIG. 2, the signal outputted by the current detector 108 on the basis of the signal outputted by the current monitor 118 when the processing gas composed of plural materials is supplied in the processing chamber 103 to process the wafer 110 is shown as the graph. In the embodiment, there is shown an example in which plural kinds of gases composing the processing gas are supplied at the flow rates per unit time of SF₆/O₂/Ar=200/10/5 cc and FIG. 2 shows the signal outputted by the current detector 108 in case where the etching processing is performed as change in the current value versus change in time.

In FIG. 2, among the currents obtained from the current detector 108, the current showing a positive value is current caused by positive ions generated by exciting particles such as gas in plasma and the current showing a negative value is current obtained by superimposing current caused by electrons on current caused by negative ions similarly. Since plasma has generally the characteristic having electrical neutrality, the sum total 201 of current values in times that positive values are shown in FIG. 2 (value obtained by integrating current values showing positive values by time) is equal to the sum total 202 of negative currents.

On the other hand, it is understood that an absolute value of an extreme value (minimum value) of current caused by electrons is larger than an absolute value of the maximum value of positive current from difference in ease of movement (velocity, temperature, dimension of mean free path and the like) due to difference in mass between electrons and ions. That is, it means that current caused by electrons flows in a moment and current caused by ions flows slowly. The currents are classified from this fact so that the current caused by electrons has relatively high frequency component and the current caused by ions has low frequency component when the waveform of current for change in time is analyzed for each frequency.

FIG. 3 is a circuit diagram schematically illustrating the current detector in the plasma processing apparatus according to the embodiment shown in FIG. 1. The current detector 108 in FIG. 3 includes, broadly divided, two electrical circuits 301A and 301B connected to one terminal of the current monitor 118 in parallel. In the embodiment, each of the electrical circuits constitutes a so-called integration circuit including a diode and a resistor connected electrically in series and a capacitor having one end connected to the ground and the other terminal connected to one end of the resistor.

In such a current detector 108, the signal representing the current detected by the current monitor 118 is supplied to the circuits 301A and 301B connected electrically in parallel to the terminal and further supplied to a forward-direction single diode 302 and a reverse-direction single diode 303 of the respective circuits. Further, the signals pass through the respective integration circuits each composed of the resistor connected to the other end of the single diode and the capacitor and are outputted from the circuits 301A and 301B as outputs A 304 (positive current) and B 305 (negative current) which are currents flowing between both terminals of the capacitors.

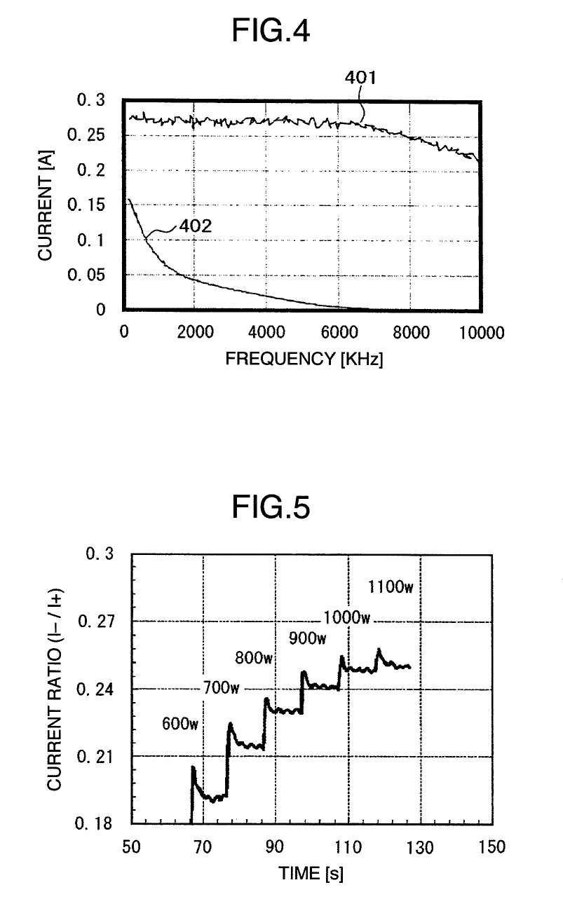

Referring to FIG. 4, electrical frequency characteristics of the circuit of the current detector 108 are described. FIG. 4 is a graph showing the electrical frequency characteristic of the current detector shown in FIG. 3.

In FIG. 4, two lines representing the frequency characteristics in which current values are changed in response to change in frequency on the horizontal axis are shown. The line 401 represents the frequency characteristic of the output A of FIG. 3 and the line 402 represents the frequency characteristic of the output B of FIG. 3. In the frequency characteristic shown by the line 401, change in the current value is relatively small until about 6000 kHz and is slowly reduced over 6000 kHz, while in the frequency characteristic shown by the line 402, the current value is sharply reduced as the frequency is increased until the frequency exceeds 2000 kHz and thereafter the current value is gradually reduced to 0 as the frequency is increased.

This example shows the line 401 representing the relatively flat frequency characteristic and the line 402 representing the frequency characteristic in case where the circuit acts as a low-pass filter in which current at relatively low frequency band flows larger, although circuits having various frequency characteristics may be used for the current detector 108. For example, it can be realized by selecting a combination in which a desired result can be attained from among plural combinations of constants of elements such as a resistance value of the register (R), a capacitance value of the capacitor (C) and a current characteristic of the diode constituting the integration circuit of the embodiment.

The current detector 108 of the embodiment detects the current represented by the line 401 showing the waveform of the flat frequency characteristic having the relatively small change until 7000 kHz as the output A 304 and the current represented by the line 402 showing the waveform of the frequency characteristic in which the current is sharply reduced from the vicinity of 0 kHz to 2000 kHz and thereafter is gradually reduced toward 8000 kHz as the output B 305. The negative current value of the output B 305 contains a lot of current components caused by negative ions before electrons in accordance with the frequency characteristic owned by the circuit 301B acting as the low-pass filter.

The signals of the outputs A 304 and B 305 can be used to detect change in the balance of positive ions and negative ions in plasma from the ratio of negative current and position current or the difference therebetween. Hereinafter, such a ratio of negative current and positive current is named the positive and negative current ratio (I−/I+). The positive current and the negative current compared in the positive and negative current ratio in the embodiment are the currents obtained by time-integrating or time-averaging the current values outputted from the outputs A 304 and B 305 by common time.

FIG. 5 is a graph showing change in the positive and negative current ratio (I−/I+) versus change in time using as a parameter the intensity (power) of the electric field supplied when plasma etching is performed on predetermined conditions in the plasma processing apparatus according to the embodiment shown in FIG. 1.

This example shows change in the current ratio versus change in power (every 100 W from 600 W to 1100 W) in case where Cl₂ is used as the processing gas to form plasma and perform the etching processing. It is understood that the positive and negative current ratio is increased with increase of the supplied power as shown in this graph.

It is considered that the reason is that the ratio of dissociating the introduced Cl₂ gas is increased and the number of negative ions (Cl—) is increased as the supplied power is increased. The inventors of the present invention obtain the knowledge that the circuits having different frequency characteristics can be used to detect change in the ratio of positive and negative ions and utilize this knowledge to recollects that the degree of progress and the end of processing using plasma or change in formation of plasma or condition of processing is judged, so that the present invention is considered.

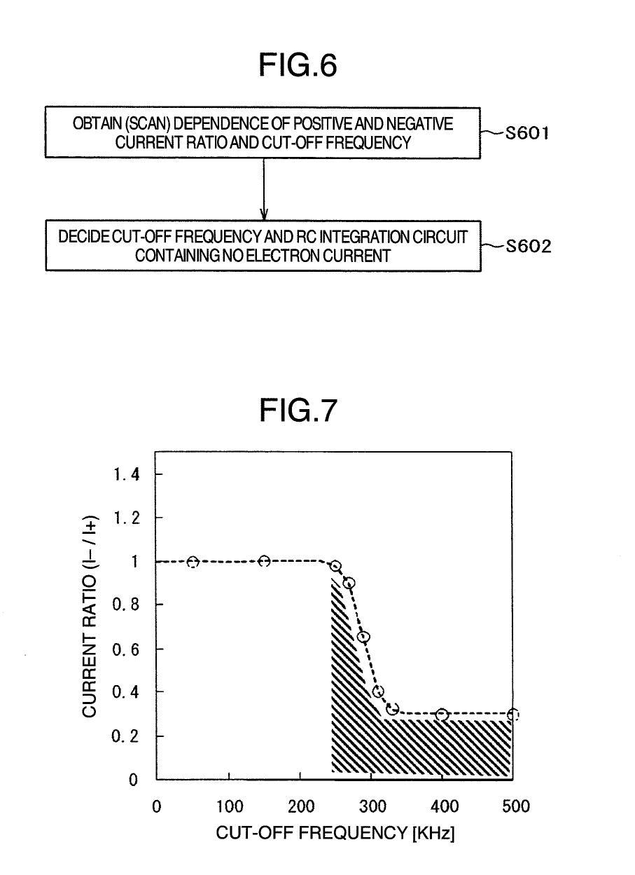

Referring to FIG. 6, an example of setting the constants of elements of the integration circuits used in the current detector 108 is described. FIG. 6 is a flow chart showing the flow of setting the constants of elements constituting the circuit of the current detector shown in FIG. 3.

In FIG. 3, the elements of the integration circuits having the resistors (R) and the capacitors (C) connected therein have the constants which can be adjusted variably. For example, the resistors are variable resistance elements and the capacitors are variable capacitance elements (variable capacitors). The plasma processing apparatus 100 including the current detector 108 provided with such circuits 301A and 301B is used to process the wafer 110 put on the putting stage 111 in the processing chamber 103 previously by forming plasma in the processing chamber 103.

The wafer at this time has the same external shape as the wafer 110 to be later subjected to the etching processing for fabricating the semiconductor device and the layer structure formed on the surface of the wafer to have the same material, thickness and disposition in the up and down direction, that is, a so-called same specification. Further, the processing conditions such as material, composition and flow rate of the processing gas, pressure in the processing chamber, intensity and distribution of electric field and magnetic field and the like are also the same.

During such a previous processing of the wafer 110, the outputs from the current detector 108 are used to detect information of the positive and negative current ratio (I−/I+) as signal data while changing the constants of elements, for example, resistance values and capacitance values, constituting the integration circuits of the circuits 301A and 301B and the signal data is recorded in a semiconductor memory or a recording device such as hard disk, CD-ROM and DVD-ROM not shown. Data of change in the positive and negative current ratio versus change in the cut-off frequency decided from the constants of elements of the circuits 301A and 301B is obtained from the recorded data (S601).

FIG. 7 is a graph showing change in a value of the positive and negative current ratio detected by the current detector of the embodiment shown in FIG. 1 versus change in the cut-off frequency along the flow of operation shown in FIG. 6. This example shows the change in the positive and negative current ratio at the time that the plasma formed on the condition of the same flow rate SF₆/O₂/Ar=200/10/5 cc as that in the example of FIG. 5 is used to subject the wafer 110 to etching processing.

The circuit of the current detector 108 uses the circuits 301A and 301B. The integration circuits which produce the output A 304 from the circuit 301A and the output B 305 from the circuit 301B use the above condition. Particularly, in this example, the resistance value of the variable resistor and the capacitance value of the variable capacitor constituting the integration circuit of the circuit 301B are changed to thereby change the cut-off frequency of the circuit 301B which produces the negative current. Further, the cut-off frequency FC, the resistance value R and the capacitance value C of the capacitor have the relation of RC=½πFC.

Further, FIG. 7 shows change in the positive and negative current ratio obtained on the basis of the outputs from the current detector 108 versus change in the cut-off frequency from data recorded in a recording device in step S601 of FIG. 6. As shown in FIG. 7, the positive and negative current ratio is 1 in the vicinity that the cut-off frequency is 0 and the positive and negative current ratio is not changed or is merely changed slightly to the degree that the ratio is regarded as being unchanged substantially within the range from the vicinity of 0 to the frequency of about 250 kHz. It is said that the positive and negative current ratio is within the range that it is regarded as being 1 substantially.

On the other hand, when the cut-off frequency exceeds 250 kHz, the positive and negative current ratio becomes suddenly smaller and after this sudden reduction is made until the vicinity of 300 kHz, the positive and negative current ratio becomes 0.3 to 0.4 and change in the positive and negative current ratio becomes small to be regarded as being a substantially fixed value again. It is considered that the reason causing such a change is that a relatively high-frequency component of current caused by electrons contained in the negative current outputted from the circuit 301B is reduced through the integration circuit of the circuit 301B operating as the low-pass filter and the negative current at low frequency caused by negative ions is a main component of the output from the circuit 301B.

From this fact, the inventors of the present invention have obtained the knowledge that the constants of the elements in the circuit 301B which outputs at least negative current can be selected properly to set the cut-off frequency of the circuit within the range in which the components caused by electrons in plasma contained in the output of the circuit 301B can be reduced sufficiently and the correlation between change in the ratio of positive and negative ions in plasma and change in characteristics of plasma can be detected with high accuracy. Particularly, by setting the cut-off frequency within such a range, the ratio of positive and negative currents outputted from the current detector 108 can be set within the range in which the ratio is smaller than 1.

In the embodiment, the cut-off frequency is set to 250 kHz or more. On the other hand, at the frequency lower than or equal to this value, the positive and negative current ratio cannot be set to a desired value smaller than 1. Further, when it is considered that the component of current caused by electrons is desirably removed as much as possible, the constants of circuits of the current detector 108 are desirably set within the range in which the cut-off frequency becomes small after the positive and negative current ratio is suddenly reduced with increase of the cut-off frequency and the ratio becomes fixed or becomes small to the degree that the ratio is regarded as becoming fixed again.

In the embodiment, the constants of elements containing the resistance values of the variable resistors and the capacitance values of the variable capacitors of the circuit are set selectively so that the cut-off frequency obtained from the constants is 350 kHz or more. In this manner, the constants of the circuits of the current detector 108 can be set properly to obtain the current ratio caused by the positive and negative ions with high S/N ratio (S602). Further, when the proper cut-off frequency is different depending on the frequency of the bias power supply 117 and processing conditions by plasma, it is preferable that the proper constants of elements of the circuits and the cut-off frequency decided by the constants are selected to be set along the flow of FIG. 6 in accordance with the respective cases.

Further, the circuit used in the embodiment is only the integration circuit using the diodes, the resisters and the capacitors and the constants of the elements are properly selected to be set in accordance with the current value detected during the previously performed processing, although even if another circuit except the above circuit is used, the frequency characteristic of the circuit can be set properly to obtain the current ratio caused by positive and negative ions with high accuracy. For example, an integration circuit using a diode circuit and an LC circuit, a circuit using an operational amplifier which can obtain more stable integration waveform or the like can be used.

Further, an LC circuit including a variable reactance L and a variable capacitor C can be used as the integration circuit. Furthermore, the plasma processing apparatus of the embodiment is configured to form plasma using microwave, although a unit to form plasma is not limited to the above configuration but the positive and negative current ratio can be detected with high accuracy by the current detector 108 of the embodiment even in the etching processing apparatus which forms inductive plasma using an induction coil or forms plasma by so-called parallel flat plates forming plasma between electrodes opposite in the up and down direction, for example.

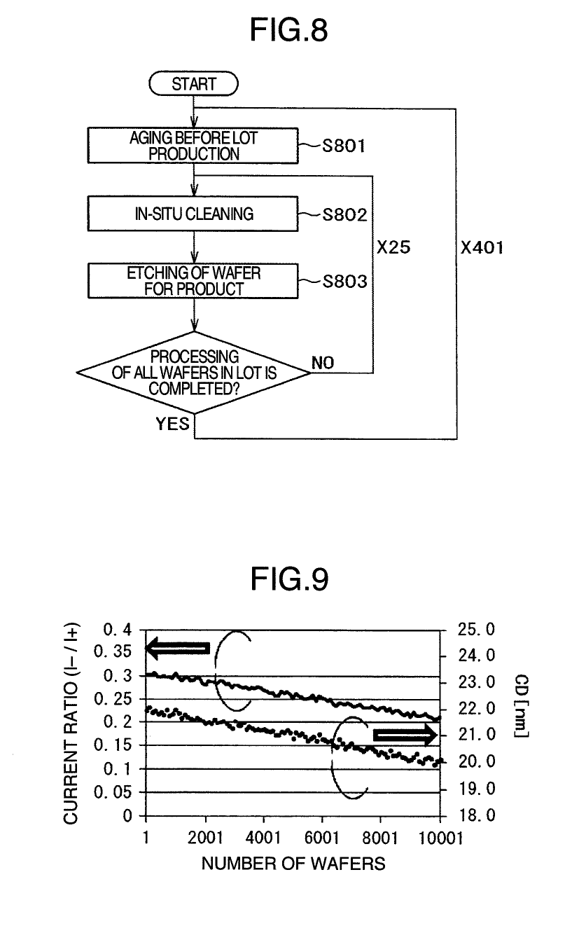

Referring to FIGS. 8 to 10, an example of adjusting the CD value in the etching processing of the wafer using the detection result of the positive and negative current ratio described above is described. FIG. 8 is a flow chart showing the flow of operation in case where a plurality of wafers are processed in the embodiment shown in FIG. 1, FIG. 8 shows an example in which about ten thousand and twenty-five wafers are processed.

In FIG. 8, the plasma processing apparatus 100 of the embodiment performs the aging processing in which plasma is formed in the processing chamber 103 before the beginning of the processing for each of lots each including usually 25 wafers set as a group to make the surface of material disposed in the processing chamber 103 fit in with the plasma and approach the state in which plasma is formed by performing the processing for a long time. That is, aging step S801 before lot production is performed.

Thereafter, the processing of wafers 110 belonging to each lot is started and in-situ cleaning step S802 is performed in which adhesion such as products attached to the inner surface of the processing chamber 103 is removed using plasma for each of the predetermined number of wafers. In the embodiment, the in-situ cleaning step S802 is performed before the beginning of the etching processing step S803 of the wafer 110 for a product.

Further, such cleaning and processing of wafer are performed repeatedly by the number of all wafers (25 times) in a lot and the processing results for 401 lots are shown in FIG. 9. The wafer 110 in this example has the layer structure in which SiN/Poly-Si/SiO₂ are laminated or piled up in order of description from above and Poly-Si is etched using a hard mask of SiN. Furthermore, a target of the CD value of the shape obtained after processing is set to 22 nm.

In the condition in the in-situ cleaning step S802, SF₆/Ar gas is used to use bias power 300 W. The etching is performed by plural steps and Cl₂/O₂ is introduced as the processing gas and bias power 100 S is applied in the main etching condition of the first step. HBr/O₂ is introduced as the processing gas and bias power 30 W is applied in the over-etching condition of the second step.

FIG. 9 is a graph showing change in the CD value after the etching processing and change in the positive and negative current ratio during the in-situ cleaning versus increase of the number of wafers to be processed in case where the plasma processing apparatus according to the embodiment shown in FIG. 1 is used to etch plural wafers in accordance with the flow shown in FIG. 8. The positive and negative current ratio is the ratio of the outputs A 304 and B 305 of the circuits 301A and 301B of the current detector 108 in which the constants of the elements and the cut-off frequency are set in accordance with the example shown in FIGS. 6 and 7.

The reason using the positive and negative current ratio in the in-situ cleaning step S802 is that there are some cases where the state on the inner wall surface of the processing chamber 103 causing variation in the CD value in the processing of the cleaning step S802 rather than the etching processing is more clearly reflected to change the positive and negative current ratio. The positive and negative current ratio shows an averaged value in all the processing time in the in-situ cleaning step S802. The CD value and the positive and negative current ratio show values for the first wafer every 4 lots (100 wafers).

As a result, there is correlation between the positive and negative current ratio (I−/I+) and the CD value in the in-situ cleaning step S802 and the CD value is expressed by the following relation with the positive and negative current ratio (I−/+).

CD=20.0×(I−/I+)+15.9 (1)

The CD after the etching processing of wafer can be predicted from the above expression (1) by using the positive and negative current ratio in the in-situ cleaning step S802. In the embodiment, the condition of the etching processing of the wafer 110 after the in-situ cleaning step S802 can be changed on the basis of the predicted value to suppress variation in the CD.

As the condition of processing for controlling the CD, the processing time of over-etching in the second step of the etching processing is given, for example. In the embodiment, it is understood that the CD is reduced by 0.3 nm per second of the over-etching time in the etching processing and the CD value is adjusted by adding seconds of the over-etching time to a value obtained by multiplying the inverse of 0.3 by difference between the CD value represented by the expression (1) and the target CD value of 22 nm.

Further, the adjustment of the predicted value of the CD value and the conditions of the etching processing is made by a control part not shown. The control part may be mounted in the plasma processing apparatus 100 or may be installed in a position separated from a place of a building in which the plasma processing apparatus 100 is installed while being connected to be able to make communication by means of a communication unit. Further, the control part includes a communication interface with which a signal is transmitted or received between the inside and the outside, an arithmetic unit such as MPU, a semiconductor memory and a recording device such as a hard disk and CD-ROM which are connected to be able to make communication by the communication unit. Such a control part may be attained by a host computer which is disposed to be able to make communication with plural apparatuses containing the plasma processing apparatus of FIG. 1 to adjust the operation thereof and controls operation of a building in which these devices are installed.

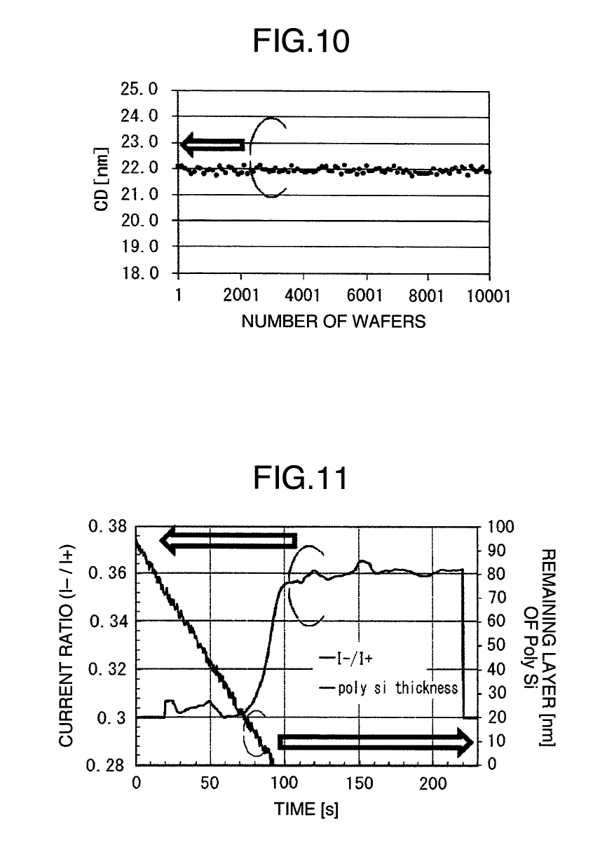

FIG. 10 is a graph showing change in the CD value after processing versus increase in the number of processed wafers obtained in case where the conditions of the etching processing are adjusted on the basis of the CD value predicted by the expression (1) in the plasma processing apparatus according to the embodiment shown in FIG. 1. This example shows the CD value in case where the over-etching time during the etching processing is adjusted to perform mass production of about ten thousand and twenty-five wafers versus the number of processed wafers expressed on the horizontal axis.

As shown in FIG. 10, it is understood that variation in the CD value during processing of 10025 wafers is ±0.3 nm and is reduced from variation in the CD value of ±2.0 nm as compared with the example shown in FIG. 9. In the embodiment, the processing time of over-etching which is the processing condition is controlled on the basis of CD predicted on the basis of the positive and negative current ratio detected by the current detector 108 to attain the long-term stabilization of CD. However, the method of controlling CD is not required to be the processing time of over-etching. For example, CD can be controlled in accordance with the gas ratio or RF bias or pressure in main etching and these may be used as control knob. Further, the positive and negative current ratio during in-situ cleaning is monitored, while the processing conditions may be changed dynamically on the basis of the positive and negative current ratio measured during aging or processing of dummy wafer or processing of the wafer of a product.

In the embodiment, the technique of stabilizing the CD value of etching processing in which the layer structure of SiN/Poly-SiISiO₂ is gate-processed during the long-term processing or processing of plural wafers has been described. The above technique can be applied to another etching process such as hard mask processing.

For example, in the process for processing the hard mask, an organic layer such as photoresist, BARC (Bottom Anti-Reflection Coating) and ACL (Amorphous Carbon Layer) is used to subject the insulating layer to be processed to etching processing. The relation of the time of processing for trimming the photoresist and change in the CD value or the relation of the time of over-etching BARC or ACL and change in the CD value can be obtained by previously making experiments or actually processing plural wafers to detect the CD value. Accordingly, the obtained relation may be used to adjust the conditions of etching processing such as the time for the trimming processing of photoresist or the over-etching of BARC or ACL on the basis of a value of difference between the target CD value and the CD value predicted on the basis of the positive and negative current ratio detected using the current detector 108 of the embodiment.

As described above, according to the embodiment, there can be provided the plasma processing apparatus which can perform processing with high accuracy by adjusting formation of plasma or processing conditions on the basis of the result of detecting change in the amounts of positive and negative ions in plasma in the processing chamber.

### Embodiment 2

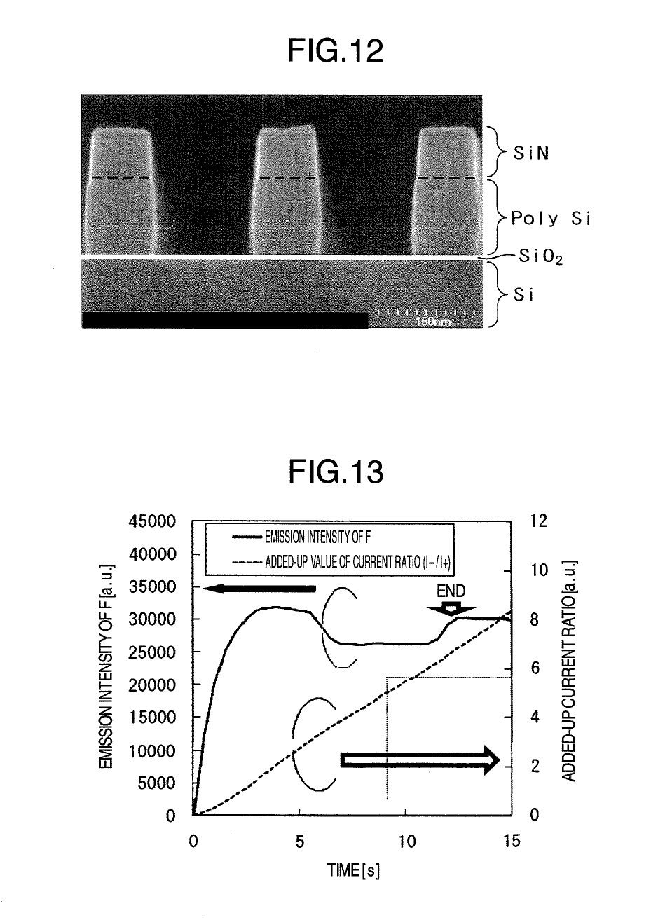

Referring now to FIGS. 11 and 12, an example of judging the end of etching processing on the basis of the positive and negative current ratio detected from the outputs of the current detector in the plasma processing apparatus according to the embodiment shown in FIG. 1 is described. The matters which are described in the embodiment 1 but are not described in this embodiment can be applied even to this embodiment unless there are special circumstances.

In this example, as wafers for judging the end of the etching processing, the wafers having the layer structure of SiN hard mask/Poly-Si/SiO₂/Si on the surface are used. Such plural wafers are subjected to the etching processing for about 220 seconds while the CF₄/O₂/Ar are introduced as the processing gas into the processing chamber 103 at the flow rates of 150/3/40 cc, respectively, and 100 W is applied as bias power.

During such processing, the current ratio of positive and negative currents detected by the current detector 108 and change in the current ratio are detected. Further, a layer thickness monitor using interference light to detect remaining thickness of the Poly-Si layer (initial thickness of the layer is 90 nm) during the processing is used to detect change in the remaining layer thickness during the etching processing.

FIG. 11 is a graph showing change in the positive and negative current ratio and the remaining thickness of the layer to be processed obtained during the etching processing using the plasma processing apparatus according to the embodiment shown in FIG. 1. This drawing shows outputs of the positive and negative current ratio and the remaining layer thickness of Poly-Si detected by the current detector 108 versus change in time during about 220 seconds necessary for the etching processing.

In this drawing, it is understood that the remaining layer thickness of Poly-Si reaches 0 nm in about 90 seconds. On the other hand, it is understood that the positive and negative current ratio is not almost changed until about 80 seconds and is suddenly changed near 90 seconds before and after the end.

This reason is that material and substance of the reacted layer are changed before and after the end of Poly-Si and accordingly the kinds of radicals and ions in plasma and respective formation or consumption amounts are changed, so that an amount of byproducts caused thereby is changed greatly. It is considered that the positive and negative current ratio showing the amounts and the balance in density of positive and negative ions in plasma is changed greatly due to variation in the amount and distribution of substance in plasma. It is understood from such knowledge that the positive and negative current ratio can be detected to judge the end of the etching processing. In the plasma processing apparatus of the embodiment, after the judgment (detection) of the end, the etching is ended or the etching processing conditions such as the kind, flow rate, pressure and the like of gas are changed to perform over-etching.

As the detailed technique of judging the end, the technique of using a predetermined value of the positive and negative current value as a threshold to judge the time when it is detect that the threshold is exceeded or the value is reduced to be lower than the threshold as the arrival time at the end or the technique of detecting an extreme value (zero-crossing) obtained by subjecting the output signal of the positive and negative current value to primary difference and secondary difference can be used. In the embodiment, the threshold of the positive and negative current ratio is set to 0.33 and the end of etching is judged on the basis of comparison of the positive and negative current ratio obtained from the output of the current detector 108 with the threshold.

FIG. 12 is a sectional view showing the layer structure in case where judgment of the end has been made using the output of the current detector of the plasma processing apparatus according to the embodiment shown in FIG. 1. The section of the layer structure in which the judgment result of the etching end based on the positive and negative current ratio has been obtained is shown as an SEM image. As shown in this drawing, it is understood according to the judgment of the end in the plasma processing apparatus of the embodiment that there is no omission in the undercoated oxide layer and Poly-Si can be etched until its undermost part properly.

In the embodiment, an example of the judgment of the end in the processing of the wafer having the layer structure composed of layers of SiN hard mask/Poly-Si/SiO₂/Si from above in order of description has been described, although material to be etched is not limited to this example and the judgment of the end can be made even for SiN (SiO₂ of foundation). In this manner, the technique of judgment of the end according to the embodiment can be applied to the etching process in which it can be detected that the positive and negative current ratio can be changed due to balance in amounts of positive and negative ions in plasma before and after the end of the layer to be processed.

As described above, according to the embodiment, there can be provided the plasma processing apparatus which can judge the processing end with high accuracy by judging the end of etching on the basis of the detection result of change in the amounts of positive and negative ions in plasma in the processing chamber.

### Embodiment 3

Referring now to FIG. 13, description is given to the case where the detection result of the positive and negative current ratio described in the embodiment in the judgment of the end using plasma emission is used to detect the time (dead time) that the judgment of the end is not made, so that the judgment of the end is made stably. The matters which are described in the embodiment 1 but are not described in this embodiment can be applied even to this embodiment unless there are special circumstances. FIG. 13 is a graph showing change in the added-up value of the outputs of the current detector and the emission intensity in the plasma processing apparatus according to another embodiment of the present invention versus change in time. This drawing shows the emission intensity of F in plasma and the added-up value of the positive and negative current ratios obtained from the outputs of the current detector 108 versus change in time.

This example shows the result obtained when the wafer having the layer structure on the surface thereof is processed by using the plasma processing apparatus shown in FIG. 1. The layer structure to be processed has Poly-Si formed all over without omission (SiO₂ of foundation) of thickness of 20 nm, which is etched for 15 seconds on the condition that gas of CF₄/O₂ is introduced and bias power is 100 W.

FIG. 13 shows change in emission intensity of F (fluorine) and the added-up value of the positive and negative current ratios measured by the current detector 108 at that time. In FIG. 13, the added-up value of the positive and negative current ratios (I−/I+) is a value obtained by adding up (integration by time) values obtained at intervals of 0.5 second from 0 second at the beginning until later time (seconds).

In this example, the emission intensity of F shows steep increase (initial variation) until about 3 seconds after formation of plasma and thereafter shows distinctive variation near 12 seconds. The point of time that the variation is obtained is detected as the end of Poly-Si layer. In this example, a threshold is used as a reference of judging the end and when the threshold is exceeded, the end of etching is detected.

For example, when the time that the threshold of thirty thousand counts are exceeded is defined as the end of etching, there exist two places near 3 to 5 seconds and near 12 seconds. The result of detecting distinctive variation near 12 seconds among them is used correctly to make judgment and accordingly the judgment excepting time named the dead time is defined by the user to thereby prevent wrong judgment. In the case of this example, it is preferable that the dead time is set about 9 seconds.

When a fixed dead time is used, it is apprehended that wrong judgment is made if the etching rate is varied during mass production to change the optimum dead time. Accordingly, in this example, a threshold is set in the added-up value of the positive and negative current ratios and when the threshold is exceeded, judgment is started.

In FIG. 13, when the added-up value of the current ratios exceeds the threshold of 5.1, judgment is started. The change in such an optimum dead time is caused by changing the etching rate for deciding the time of the end by influence of the ion density and its balance. Accordingly, the threshold is set in the added-up value of the positive and negative current ratios before the dead time is provided, so that when the threshold is exceeded, judgment is started to thereby judge the end more stably.

For example, even when the end time becomes early as the etching rate is fast, detection of plasma emission for judgment can be started in an earlier time zone than the time of the end by the decision method of the judgment start time using the added-up value of the positive and negative current ratios. Further, in the embodiment, the added-up value of (I−/I+) is used as the positive and negative current values, although the added-up value of (I+/−) may be used as the positive and negative current values. This reason is that positive and negative of ions having the strong correlation with the etching rate are changed depending on the kind of gas and byproducts.

As described above, according to the embodiment, there can be provided the plasma processing apparatus which can judge the processing end with high accuracy by setting the threshold in the added-up value of the positive and negative current ratios and starting judgment for detection of the end when the threshold is exceeded.

Further, the present invention is not limited to the above embodiments but various modifications may be contained. For example, the above embodiments are described in detail in order to describe the present invention in plain and the present invention is not necessarily limited to the apparatus containing all constituents described above. Furthermore, part of the constitutions of a certain embodiment may be replaced by the constitution of another embodiment and the constitution of another embodiment can be added to the constitution of the certain embodiment. Moreover, addition, deletion and replacement of another constitution can be made for part of the constitution of the embodiments.

It should be further understood by those skilled in the art that although the foregoing description has been made on embodiments of the invention, the invention is not limited thereto and various changes and modifications may be made without departing from the spirit of the invention and the scope of the appended claims.

1. A plasma processing apparatus, comprising:
a processing container having a processing chamber disposed therein and from which processing gas is exhausted;
a unit to supply an electric field in the processing chamber to form plasma using processing gas supplied in the processing chamber;
a putting stage disposed in the processing chamber to put a wafer thereon;
a bias power supply to supply high-frequency power to an electrode disposed in the putting stage; and
a detection part to detect amounts of positive and negative currents flowing between the bias power supply and the putting stage and detect a ratio of a negative current amount (I−) and a positive current amount (I+) from which part caused by electrons in the plasma is removed, wherein
formation of the plasma or processing condition using the plasma of a layer to be processed and disposed on the wafer is adjusted in accordance with the ratio.

2. A plasma processing apparatus, comprising:
a processing container having a processing chamber disposed therein and from which processing gas is exhausted;
a unit to supply an electric field in the processing chamber to form plasma using processing gas supplied in the processing chamber;
a putting stage disposed in the processing chamber to put a wafer thereon,
a bias power supply to supply high-frequency power to an electrode disposed in the putting stage; and
a detection part to detect amounts of positive and negative currents flowing between the bias power supply and the putting stage and detect a ratio of a negative current amount (I−) and a positive current amount (I+), wherein
formation of the plasma or processing condition using the plasma of a layer to be processed and disposed on the wafer is adjusted in accordance with a value in a range in which the ratio (I−/I+) is smaller than 1.

3. The plasma processing apparatus according to claim 1, wherein
the detection part detects the ratio of the negative current amount caused by negative ions in the plasma and the positive current amount caused by positive ions in the plasma.

4. The plasma processing apparatus according to claim 1, wherein
the detection part detects the ratio of the negative current amount and the positive current amount at a lower frequency than a predetermined value.

5. The plasma processing apparatus according to claim 4, wherein
the detection part includes an integration circuit having elements containing at least a resistor or a coil and a capacitor and connected electrically and which produces the negative or position current amount.

6. The plasma processing apparatus according to claim 5, wherein
the integration circuit has a cut-off frequency in which the ratio (I−/I+) of the positive and negative current amounts is smaller than 1.

7. The plasma processing apparatus according to claim 6, wherein
the current amount detected during processing of another wafer which is previously processed is used to set constants of the elements by which the cut-off frequency is obtained.

8. The plasma processing apparatus according to claim 1, wherein
the processing condition using the plasma is processing time of over-etching.

9. The plasma processing apparatus according to claim 1, wherein
an end of processing using the plasma is detected on basis of change in the ratio.

10. The plasma processing apparatus according to claim 1, wherein
a threshold set in an added-up value of the ratios is used as reference of starting judgment for detection of an end in judgment of the end using light emission of the plasma.
